(19) United States
(12) Patent Application Publication
(10) Pub. No.: US 2025/0072000 A1
(43) Pub. Date: Feb. 27, 2025

(54) SEMICONDUCTOR MEMORY DEVICE

(71) Applicant: SK hynix Inc., Icheon-si Gyeonggi-do (KR)

(72) Inventor: Sung Wook JUNG, Icheon-si Gyeonggi-do (KR)

(73) Assignee: SK hynix Inc., Icheon-si Gyeonggi-do (KR)

(21) Appl. No.: 18/435,064

(22) Filed: Feb. 7, 2024

(30) Foreign Application Priority Data
Aug. 23, 2023 (KR) 10-2023-0110513

(51) Int. Cl. H10B 43/40; H01L 23/00; H01L 25/065; H01L 25/18; H10B 43/27; H10B 80/00; G11C 16/08

(52) U.S. Cl. CPC H10B 43/40; H01L 24/08; H01L 25/0657; H01L 25/18; H10B 43/27; H10B 80/00; G11C 16/08; H01L 2224/08145; H01L 2924/1431; H01L 2924/14511

(57) ABSTRACT

There is provided a semiconductor memory device. The semiconductor memory device includes a first peripheral circuit structure, a cell array structure, a mold insulating structure disposed between the first peripheral circuit structure and the cell array structure, and a second peripheral circuit structure disposed in the mold insulating structure and including a pass transistor.

### CROSS-REFERENCE TO RELATED APPLICATION

The present application claims priority under 35 U.S.C. § 119(a) to Korean patent application number 10-2023-0110513 filed on Aug. 23, 2023, in the Korean Intellectual Property Office, the entire disclosure of which is incorporated by reference herein.

### BACKGROUND

### 1. Technical Field

The present disclosure generally relates to a semiconductor memory device, and more particularly, to a three-dimensional semiconductor memory device.

### 2. Related Art

Semiconductor memory devices are applied to electronic devices of various fields, such as automobiles, medical care, and data centers, as well as small electronic devices. Accordingly, demand for semiconductor memory devices is increasing.

The semiconductor memory device may include a memory cell for data storage. In order to increase a capacity of the semiconductor memory device, technology development for a three-dimensional semiconductor memory device including memory cells arranged in a three-dimension is being actively progressed.

### SUMMARY

According to an embodiment of the present disclosure, a semiconductor memory device may include a plurality of transistors, a lower insulating structure covering the plurality of transistors, a global line disposed within the lower insulating structure, a mold insulating structure disposed over the lower insulating structure and including a first area overlapping the global line and a second area extending laterally from the first area, a pass gate disposed in the first area of the mold insulating structure, an active pillar passing through the pass gate and contacting the global line, a pass gate insulating layer located between the active pillar and the pass gate, a first conductive connection structure disposed in the second area of the mold insulating structure, and a cell array structure including a plurality of memory cells arranged in a three dimension over the mold insulating structure.

According to an embodiment of the present disclosure, a semiconductor memory device may include a first peripheral circuit structure including a block decoder, a gate stack spaced apart from the first peripheral circuit structure in a first direction and including a plurality of conductive layers spaced apart and stacked in the first direction, a mold insulating structure disposed between the gate stack and the first peripheral circuit structure and including a first area overlapping the block decoder and a second area extending laterally from the first area, and a second peripheral circuit structure disposed within the first area of the mold insulating structure and including a plurality of pass transistors configured to operate in response to a block select signal output from the block decoder.

### BRIEF DESCRIPTION OF THE DRAWINGS

FIG. 1 is a block diagram illustrating a semiconductor memory device according to an embodiment of the present disclosure.

FIG. 2 is a circuit diagram illustrating a memory cell array and a pass circuit according to an embodiment of the present disclosure.

FIGS. 3 and 4 are cross-sectional views illustrating semiconductor memory devices according to embodiments of the present disclosure.

FIG. 5A is a cross-sectional view illustrating a pass transistor group according to an embodiment of the present disclosure, and FIG. 5B is a plan view illustrating the pass transistor group taken along a line A-A′ shown in FIG. 5A.

FIGS. 6A, 6B, 6C, 6D, 6E, 6F, 6G, 6H, 6I, 6J, 6K, and 6L are cross-sectional views illustrating a method of manufacturing a first conductive connection structure and a pass transistor group of a semiconductor memory device according to an embodiment of the present disclosure.

FIG. 7 is a block diagram illustrating an electronic system including a semiconductor memory device according to an embodiment of the present disclosure.

### DETAILED DESCRIPTION

Specific structural or functional descriptions of the embodiments according to the concept of the present disclosure disclosed in the present specification or application are exemplified to describe the embodiments according to the concept of the present disclosure. The embodiments according to the concept of the present disclosure are not to be construed as being limited to the embodiments described in the present specification or application, and may be variously modified and replaced with other equivalent embodiments.

It will be understood that, although the terms “first,” “second,” etc. may be used herein to describe various elements, these elements should not be limited by these terms. These terms are only used to distinguish one element from another element, and the order or number of components is not limited by the terms. In addition, it is not construed as limiting the number of components unless there is a special limitation on components expressed in singular or plural numbers. Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example of the term “below” can encompass both an orientation of above and below. The device may be otherwise oriented (rotated 90 degrees or at other orientations) and the spatially relative descriptors used herein interpreted accordingly. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present.

Various embodiments of the present disclosure may provide a semiconductor memory device capable of improving an integration degree.

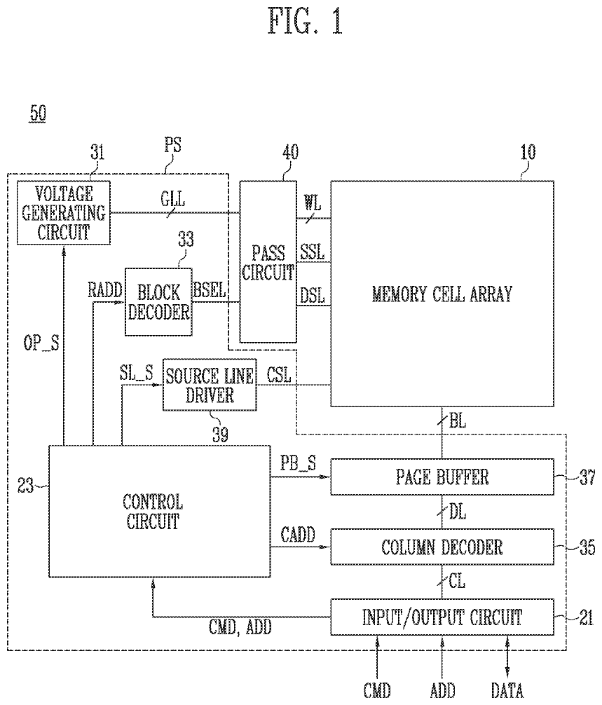

FIG. 1 is a block diagram illustrating a semiconductor memory device according to an embodiment of the present disclosure.

Referring to FIG. 1, the semiconductor memory device 50 may include a memory cell array 10, a pass circuit 40, and a peripheral circuit structure PS.

The memory cell array 10 may include a plurality of memory blocks. Each of the memory blocks may include a plurality of memory cells. Each of the memory cells may be a nonvolatile memory cell. As an embodiment, each memory cell may be a NAND flash memory cell. Hereinafter, an embodiment of the present disclosure is described based on the semiconductor memory device 50 including the NAND flash memory cell, but an embodiment of the present disclosure is not limited thereto. As another embodiment, each memory cell may be configured of a ferroelectric memory cell, a variable resistance memory cell, or the like.

The pass circuit 40 may be connected to the memory cell array 10 through a plurality of local lines. As an embodiment, the plurality of local lines may include a plurality of word lines WL, at least one source select line SSL, and at least one drain select line DSL.

The peripheral circuit structure PS may be configured to perform a program operation for storing data in the memory cell array 10, a read operation for outputting data stored in the memory cell array 10, and an erase operation for erasing data stored in the memory cell array 10. As an embodiment, the peripheral circuit structure PS may include an input/output circuit 21, a control circuit 23, a voltage generating circuit 31, a block decoder 33, a column decoder 35, a page buffer 37, and a source line driver 39.

The input/output circuit 21 may transfer a command CMD and an address ADD received from an external device (for example, a memory controller) of the semiconductor memory device 50 to the control circuit 23. The input/output circuit 21 may exchange data DATA with the external device and the column decoder 35.

The control circuit 23 may output an operation signal OP_S, a row address RADD, a source line control signal SL_S, a page buffer control signal PB_S, and a column address CADD in response to the command CMD and the address ADD.

The voltage generating circuit 31 may generate and output various operation voltages used for the program operation, the read operation, and the erase operation in response to the operation signal OP_S. The operation voltages output from the voltage generating circuit 31 may be transmitted to the pass circuit 40 through a plurality of global lines GLL.

The block decoder 33 may output a block select signal in response to the row address RADD. The block select signal output from the block decoder 33 may be transmitted to the pass circuit 40 through a block select line BSEL.

The pass circuit 40 may transfer the operation voltages transmitted to the plurality of global lines GLL to the drain select line DSL, the word line WL, and the source select line SSL in response to the block select signal transmitted to the block select line BSEL.

The column decoder 35 may transmit the data DATA input from the input/output circuit 21 to the page buffer 37 or transmit the data DATA stored in the page buffer 37 to the input/output circuit 21, in response to the column address CADD. The column decoder 35 may exchange the data DATA with the input/output circuit 21 through a column line CL. The column decoder 35 may exchange the data DATA with the page buffer 37 through a data line DL.

The page buffer 37 may store read data received through a bit line BL in response to the page buffer control signal PB_S. The page buffer 37 may sense a voltage or a current of the bit line BL during the read operation. The page buffer 37 may be connected to the memory cell array 10 through the bit line BL.

The source line driver 39 may control a voltage applied to a common source line CSL in response to the source line control signal SL_S. The source line driver 39 may be connected to the memory cell array 10 through the common source line CSL.

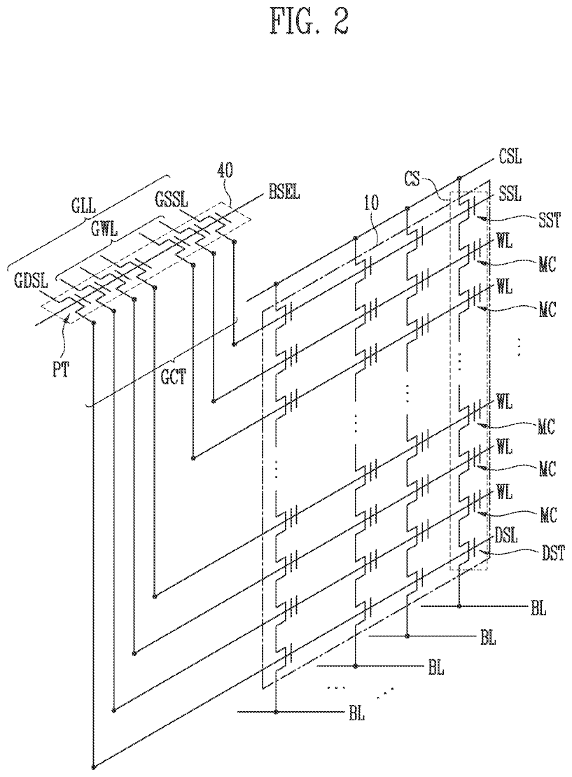

FIG. 2 is a circuit diagram illustrating a memory cell array and a pass circuit according to an embodiment of the present disclosure.

Referring to FIG. 2, the memory cell array 10 may include a plurality of memory cell strings CS. The plurality of memory cell strings CS may be connected to the plurality of bit lines BL and the common source line CSL.

Each memory cell string CS may include at least one source select transistor SST, a plurality of memory cells MC, and at least one drain select transistor DST.

The source select transistor SST may control an electrical connection between the plurality of memory cells MC and the common source line CSL. The drain select transistor DST may control an electrical connection between the plurality of memory cells MC and the bit line BL.

One source select transistor SST may be disposed or two or more source select transistors connected in series may be disposed between the common source line CSL and the plurality of memory cells MC. One drain select transistor DST may be disposed or two or more drain select transistors connected in series may be disposed between each bit line BL and the plurality of memory cells MC of the memory cell string CS corresponding thereto.

A plurality of gates of the plurality of memory cells MC may be respectively connected to the plurality of word lines WL. A gate of the source select transistor SST may be connected to the source select line SSL. A gate of the drain select transistor DST may be connected to the drain select line DSL.

The source select line SSL, the drain select line DSL, and the plurality of word lines WL may be connected to the pass circuit 40. The pass circuit 40 may include a pass transistor group, and each pass transistor group may include a plurality of pass transistors PT connected to the same block select line BSEL. The plurality of pass transistors PT may be respectively connected to a plurality of gate contact plugs GCT. The plurality of gate contact plugs GCT may be respectively connected to the source select line SSL, the drain select line DSL, and the plurality of word lines WL. Each pass transistor PT may be connected to a corresponding local line among the source select line SSL, the drain select line DSL, and the plurality of word lines WL via a gate contact plug GCT corresponding thereto.

The plurality of pass transistors PT may transfer voltages applied to the plurality of global lines GLL to the source select line SSL, the drain select line DSL, and the plurality of word lines WL in response to the block select signal applied to the block select line BSEL. The plurality of global lines GLL may include a global source select line GSSL, a global drain select line GDSL, and a plurality of global word lines GWL respectively corresponding to the source select line SSL, the drain select line DSL, and the plurality of word lines WL.

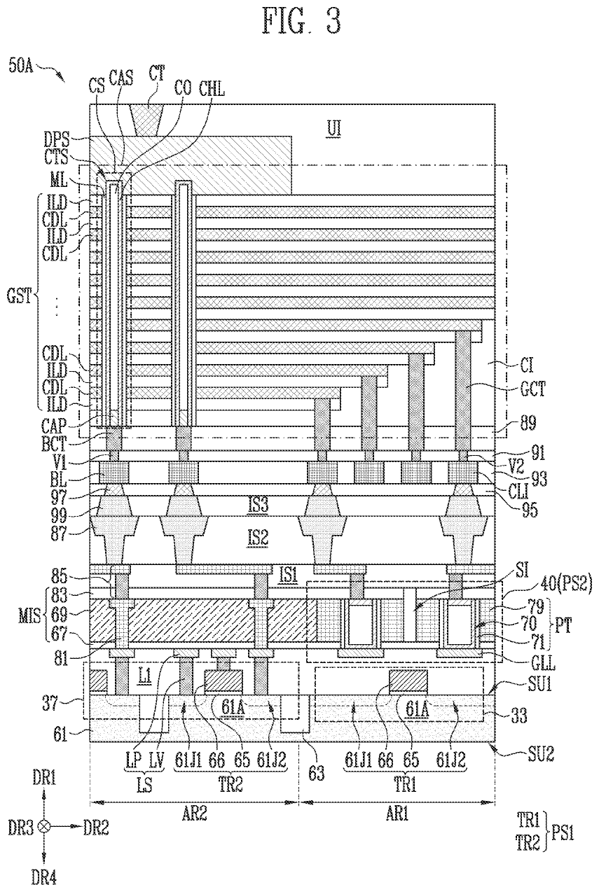

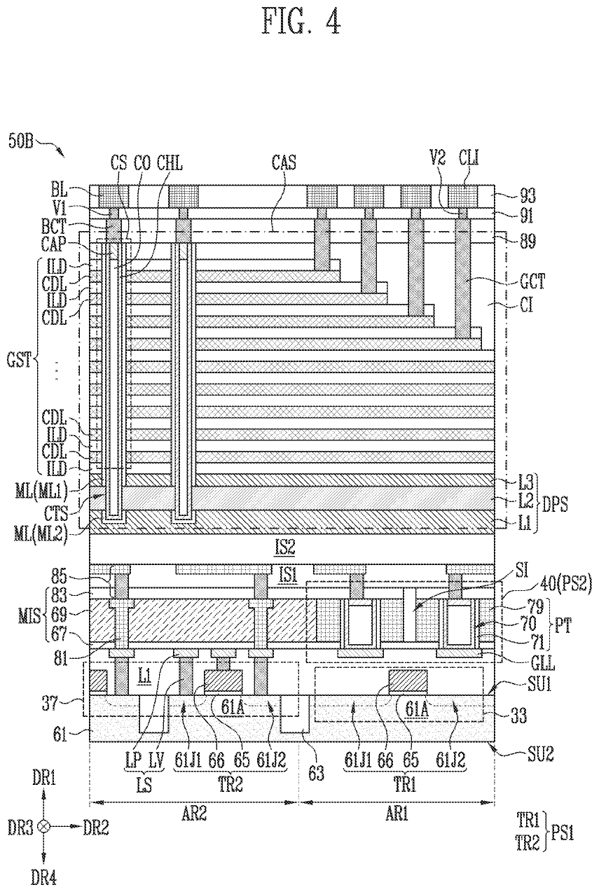

FIGS. 3 and 4 are cross-sectional views illustrating semiconductor memory devices according to embodiments of the present disclosure.

Referring to FIGS. 3 and 4, the semiconductor memory device 50A or 50B may include a cell array structure CAS, a doped semiconductor structure DPS, a first peripheral circuit structure PS1, a second peripheral circuit structure PS2, and an interconnection structure. The interconnection structure may include various conductive patterns for an electrical connection between the cell array structure CAS, the first peripheral circuit structure PS1, and the second peripheral circuit structure PS2.

The cell array structure CAS may include a plurality of memory cells arranged in three dimensions. In an embodiment, the cell array structure CAS may include a gate stack GST, a memory layer ML, and a channel layer CHL as indicated by the dotted box in FIGS. 3 and 4. As an embodiment, the plurality of memory cells may be included in the plurality of memory cell strings CS described with reference to FIG. 2. Each memory cell string CS may be connected to a plurality of conductive layers CDL included in the gate stack GST. The plurality of conductive layers CDL may serve as at least one drain select line DSL, the plurality of word lines WL, and at least one source select line SSL shown in FIG. 2. Each memory cell may be connected to a conductive layer serving as a word line among the plurality of conductive layers CDL. The channel layer CHL may serve as a channel region of each memory cell string CS, and the memory layer ML may serve as a data storage region of each memory cell string CS. The plurality of memory cells may be defined between a plurality of channel layers CHL and the plurality of word lines among the plurality of conductive layers CDL. The plurality of word lines may be stacked vertically and surround the plurality of channel layers CHL. The plurality of channel layers CHL may be arranged in two dimensions and extend vertically. In an embodiment, the cell array structure CAS may include a three-dimensional memory array defined by stacking memory cells vertically up on each memory cell which is located in the two-dimensional array.

The gate stack GST may be disposed over a semiconductor substrate 61. The semiconductor substrate 61 may include a first surface SU1 facing a first direction DR1. The gate stack GST may further include a plurality of interlayer insulating layers ILD alternately stacked in the first direction DR1 with the plurality of conductive layers CDL. Each conductive layer CDL and each interlayer insulating layer ILD may extend in a second direction DR2 and a third direction DR3 toward which axes crossing each other in a plane parallel to the first surface SU1 face. The above-described first direction DR1, second direction DR2, and third direction DR3 may be defined as directions toward which an X-axis, a Y-axis, and a Z-axis face. Hereinafter, a direction toward which a second surface SU2 of the semiconductor substrate 61 faces may be defined as a fourth direction DR4, and the second surface SU2 may be defined as a surface opposite to the first surface SU1.

The plurality of conductive layers CDL may include at least one of a doped semiconductor layer and a metal layer. The doped semiconductor layer of each conductive layer CDL may include a doped silicon layer. The metal layer of each conductive layer CDL may include tungsten, copper, molybdenum, or the like. The plurality of conductive layers CDL may further include a metal nitride layer. The metal nitride layer may include titanium nitride, tantalum nitride, or the like. The plurality of interlayer insulating layers ILD may include a silicon oxide layer or the like.

The memory layer ML and the channel layer CHL may pass through the gate stack GST. The memory layer ML and the channel layer CHL may be disposed in a channel hole extending in the first direction DR1 to pass through the plurality of conductive layers CDL and the plurality of interlayer insulating layers ILD of the gate stack GST. The channel layer CHL may be formed of a semiconductor material. As an embodiment, the channel layer CHL may include silicon, germanium, or a mixture thereof.

The channel layer CHL may include a contact surface CTS that is in contact with the doped semiconductor structure DPS. The doped semiconductor structure DPS may be used in at least one of a source region and a well region. As an embodiment, the doped semiconductor structure DPS may be provided as the source region including an n-type impurity as a majority carrier. An embodiment of the present disclosure is not limited thereto. As another embodiment, the doped semiconductor structure DPS may include at least one of a first conductivity type doped region including an n-type impurity as a majority carrier and a second conductivity type doped region including a p-type impurity as a majority carrier. The first conductivity type doped region may be provided as the source region, and the second conductivity type doped region may be provided as the well region.

The doped semiconductor structure DPS and the gate stack GST may be disposed at a position spaced apart from the semiconductor substrate 61 in the first direction DR1. The position of the doped semiconductor structure DPS and gate stack GST may be variously designed. As an embodiment, as shown in FIG. 3, the doped semiconductor structure DPS may be disposed at a position farther from the semiconductor substrate 61 than the gate stack GST in the first direction DR1. As another embodiment, as shown in FIG. 4, the doped semiconductor structure DPS may be disposed at a position closer to the semiconductor substrate 61 than the gate stack GST in the first direction DR1.

Referring to FIG. 3, the gate stack GST may be disposed between the doped semiconductor structure DPS and the semiconductor substrate 61. The contact surface CTS of the channel layer CHL may be coplanar with a sidewall of the doped semiconductor structure DPS, a surface of the doped semiconductor structure DPS facing the fourth direction DR4, and the like. As an embodiment, the doped semiconductor structure DPS may include a groove into which the channel layer CHL may be inserted, and the contact surface CTS of the channel layer CHL may be coplanar with a surface of the groove defined in the doped semiconductor structure DPS.

The gate stack GST and the doped semiconductor structure DPS may be covered with an upper insulating layer UI. A conductive contact CT may be disposed inside the upper insulating layer UI, and the conductive contact CT may be connected to the doped semiconductor structure DPS. Although not shown in the drawing, the conductive contact CT may transmit an electrical signal from a common source line disposed over the upper insulating layer UI to the doped semiconductor structure DPS.

Referring to FIG. 4, the doped semiconductor structure DPS may be disposed between the gate stack GST and the semiconductor substrate 61. The contact surface CTS of the channel layer CHL may be coplanar with a sidewall of the doped semiconductor structure DPS, a surface of the doped semiconductor structure DSP facing the first direction DR1, or the like. As an embodiment, the doped semiconductor structure DPS may include a first semiconductor layer L1, a second semiconductor layer L2, and a third semiconductor layer L3 stacked in the first direction DR1. The channel layer CHL may pass through the third semiconductor layer L3 and extend into the first semiconductor layer L1. The second semiconductor layer L2 may include a sidewall that is coplanar with the contact surface CTS of the channel layer CHL. In other words, a sidewall of the second semiconductor layer L2 may contact the channel layer CHL.

Each of the first semiconductor layer L1, the second semiconductor layer L2, and the third semiconductor layer L3 may include at least one of an n-type impurity and a p-type impurity. As an embodiment, each of the first semiconductor layer L1, the second semiconductor layer L2, and the third semiconductor layer L3 may be provided as a first conductivity type doped region including the n-type impurity as a majority carrier. As another embodiment, each of the second semiconductor layer L2 and the third semiconductor layer L3 may be provided as a first conductivity type doped region including the n-type impurity as a majority carrier, and the first semiconductor layer L1 may be provided as a second conductivity type doped region including the p-type impurity as a majority carrier. The first conductivity type doped region may be provided as the source region, and the second conductivity type doped region may be provided as the well region. An embodiment of the present disclosure is not limited thereto, and a doped region of the first semiconductor layer L1, the second semiconductor layer L2, and the third semiconductor layer L3 may be variously designed. Each of the first semiconductor layer L1, the second semiconductor layer L2, and the third semiconductor layer L3 may include a semiconductor material such as silicon.

The memory layer ML may be interposed between each of the first semiconductor layer L1 and the third semiconductor layer L3 and the channel layer CHL. The memory layer ML may be separated into a first memory layer ML1 and a second memory layer ML2 by contact between the second semiconductor layer L2 and the channel layer CHL. The first memory layer ML1 may be interposed between the third semiconductor layer L3 and the channel layer CHL, and may extend in the first direction DR1 to be interposed between the gate stack GST and the channel layer CHL. The second memory layer ML2 may be interposed between the channel layer CHL and the third semiconductor layer L3.

Referring to FIGS. 3 and 4, a core insulating layer CO and a capping pattern CAP may be disposed in a central region of the channel hole passing through the gate stack GST. The channel layer CHL may extend along a side portion of the core insulating layer CO and a side portion of the capping pattern CAP. The capping pattern CAP may serve as a drain junction of the memory cell string CS. The capping pattern CAP may include at least one of an n-type impurity and a p-type impurity. As an embodiment, the capping pattern CAP may include the n-type impurity as a majority carrier.

Each of the memory layer ML shown in FIG. 3 and the first memory layer ML1 shown in FIG. 4 may include a blocking insulating layer between the channel layer CHL and the gate stack GST, a data storage layer between the blocking insulating layer and the channel layer CHL, and a tunnel insulating layer between the data storage layer and the channel layer CHL. The blocking insulating layer may include an insulating material capable of blocking a charge. The tunnel insulating layer may include an insulating material capable of charge tunneling. The blocking insulating layer may include an insulating layer having a dielectric constant higher than that of the tunnel insulating layer. The data storage layer may be formed of a material layer that may store changed data using Fowler Nordheim tunneling. As an embodiment, the data storage layer may be formed of a charge trap insulating layer or an insulating layer including a conductive nano dot. The charge trap insulating layer may include a silicon nitride layer. An embodiment of the present disclosure is not limited thereto, and the data storage layer may be formed of a material layer capable of storing information based on an operation principle other than Fowler Nordheim tunneling. As an embodiment, the data storage layer may include a phase change material layer, a ferroelectric layer, or the like. In this case, the channel layer CHL, the core insulating layer CO, and the capping pattern CAP may be replaced with a columnar electrode structure.

The second memory layer ML2 shown in FIG. 4 may be configured the same as the first memory layer ML1.

Referring to FIGS. 3 and 4, the semiconductor memory device 50A or 50B may further include a bit line BL. The bit line BL may be disposed at a position spaced apart from the semiconductor substrate 61 in the first direction DR1. The position of the bit line BL may be variously designed. As an embodiment, as shown in FIG. 3, the bit line BL may be disposed at a position closer to the semiconductor substrate 61 than the gate stack GST in the first direction. In other words, the bit line BL may be disposed between the gate stack GST and the semiconductor substrate 61. As another embodiment, as shown in FIG. 4, the bit line BL may be disposed at a position farther from the semiconductor substrate 61 than the gate stack GST in the first direction DR1. In other words, the gate stack GST may be disposed between the bit line BL and the semiconductor substrate 61.

Referring to FIGS. 3 and 4, the bit line BL may be connected to the capping pattern CAP via a bit line connection structure disposed between the gate stack GST and the bit line BL. As an embodiment, the bit line connection structure may include a conductive bit contact plug BCT and a conductive first via structure V1. The conductive bit contact plug BCT may be disposed inside a first interlayer insulating structure 89 between the gate stack GST and the bit line BL and may be connected to the capping pattern CAP. The conductive first via structure V1 may be disposed inside a second interlayer insulating structure 91 between the first interlayer insulating structure 89 and the bit line BL, and may electrically connect the conductive bit contact plug BCT to the bit line BL. The bit line BL may be disposed within a bit line level insulating layer 93. The bit line level insulating layer 93 may overlap the first interlayer insulating structure 89 with the second interlayer insulating structure 91 interposed therebetween.

A connection between the bit line BL and the capping pattern CAP is not limited to the above-described embodiment. Although not shown in the drawing, as another embodiment, the bit line BL may be directly connected to the capping pattern CAP.

A covering insulating structure CI may be formed between the gate stack GST and the first interlayer insulating structure 89. The channel layer CHL and the capping pattern CAP may extend toward the bit line BL to pass through a portion of the covering insulating structure CI.

As an embodiment, the plurality of conductive layers CDL of the gate stack GST may include ends forming a stepped structure. At this time, the covering insulating structure CI may cover the stepped structure. An embodiment of the present disclosure is not limited thereto, and the plurality of conductive layers CDL of the gate stack GST may include ends aligned in a line without forming a stepped structure.

Referring to FIGS. 3 and 4, the semiconductor substrate 61 may include a plurality of active regions 61A partitioned by an isolation layer 63. A plurality of junction regions 61J1 and 61J2 of a plurality of transistors TR1 and TR2 may be formed in the plurality of active regions 61A.

The plurality of transistors TR1 and TR2 may configure a first peripheral circuit structure PS1, which is a portion of the peripheral circuit structure PS shown in FIG. 1. The first peripheral circuit structure PS1 may include the block decoder 33, and may include at least one of remaining configurations excluding the pass circuit 40 in the peripheral circuit structure PS described with reference to FIG. 1. As an embodiment, the first peripheral circuit structure PS1 may include the block decoder 33 and the page buffer 37. The plurality of transistors TR1 and TR2 may include a first transistor TR1 forming a portion of the block decoder 33 and a second transistor TR2 forming a portion of the page buffer 37.

The plurality of junction regions 61J1 and 61J2 may include a first junction region 61J1 and a second junction region 61J2 provided as a source junction and a drain junction of each of the first transistor TR1 and the second transistor TR2. The first junction region 61J1 and the second junction region 61J2 may include at least one conductive type impurity of an n-type impurity and a p-type impurity. As an embodiment, when each of the first transistor TR1 and the second transistor TR2 is provided as an N-channel metal oxide semiconductor (NMOS) transistor, the first junction region 61J1 and the second junction region 61J2 may include the n-type impurity as a majority carrier.

A gate insulating layer 65 and a gate electrode 66 of each of the first transistor TR1 and the second transistor TR2 may be stacked over the active region 61A of the semiconductor substrate 61 disposed between the first junction region 61J1 and the second junction region 61J2.

The gate stack GST may be spaced apart from the first peripheral circuit structure PS1 in the first direction DR1. A lower insulating structure LI may be disposed between the gate stack GST and the first peripheral circuit structure PS1. The lower insulating structure LI may be disposed over the semiconductor substrate 61 and may extend to cover the first transistor TR1 and the second transistor TR2 of the first peripheral circuit structure PS1.

A plurality of conductive lower connection structures LS and a plurality of global lines GLL may be disposed in the lower insulating structure LI. The plurality of conductive lower connection structures LS may be used as an interconnection structure. The plurality of global lines GLL may be conductive patterns transmitting operation voltages output from the voltage generating circuit 31 shown in FIG. 1.

The plurality of conductive lower connection structures LS may include a first type of conductive lower connection structure connected to the first transistor TR1 and a second type of conductive lower connection structure connected to the second transistor TR2. FIGS. 3 and 4 representatively illustrate the second type of conductive lower connection structure.

Each conductive lower connection structure LS may include a lower via structure LV and a lower pad pattern LP. The lower via structure LV may contact one corresponding thereto among the gate electrode 66, the first junction region 61J1, and the second junction region 61J2, and may extend in the first direction DR1. The lower pad pattern LP may contact the lower via structure LV. The lower pad pattern LP may include an upper surface facing the first direction DR1, and the upper surface of the lower pad pattern LP may include an opening portion that is not covered by the lower insulating structure LI.

An upper surface of each global line GLL may include an open portion that is not covered by the lower insulating structure LI and may face the first direction DR1.

A mold insulating structure MIS may be disposed between the lower insulating structure LI and the gate stack GST. The mold insulating structure MIS may include a first area AR1 overlapping the block decoder 33 and a second area AR2 extending from the first area AR1 to a side portion (for example, in the second direction DR2). The first area AR1 of the mold insulating structure MIS may overlap the plurality of global lines GLL and the first transistor TR1, and the second area AR2 of the mold insulating structure MIS may overlap the transistor TR2.

The second peripheral circuit structure PS2 and a first conductive connection structure 81 may be disposed inside the mold insulating structure MIS.

The second peripheral circuit structure PS2 may include the pass transistor group of the pass circuit 40. The pass transistor group may include the plurality of pass transistors PT. The plurality of pass transistors PT may be disposed in the first area AR1 of the mold insulating structure MIS. The plurality of pass transistors PT may be commonly connected to a pass gate 79. The pass gate 79 may serve as a gate electrode of each pass transistor PT. The block select signal output from the block decoder 33 may be transmitted to the pass gate 79 through a block select line (not shown). The pass gate 79 may be disposed in the first area AR1 of the mold insulating structure MIS. The pass gate 79 may be penetrated by the active pillar 70 of each pass transistor PT. The active pillar 70 may contact the global line GLL corresponding thereto. A pass gate insulating layer 71 of each pass transistor PT may be disposed between the active pillar 70 and the pass gate 79.

A plurality of first conductive connection structures 81 may be disposed in the second area AR2 of the mold insulating structure MIS. The plurality of first conductive connection structures 81 may be included in an interconnection structure.

The mold insulating structure MIS may include a first insulating layer 67, a second insulating layer 69, and a third insulating layer 83. The first insulating layer 67 may be disposed over the lower insulating structure LI. The first insulating layer 67 may extend along a bottom surface of the pass gate 79 facing the fourth direction DR4. The second insulating layer 69 may be disposed over the first insulating layer 67. The second insulating layer 69 may face a side surface of the pass gate 79. The third insulating layer 83 may be disposed over the second insulating layer 69. The third insulating layer 83 may extend along an upper surface of the pass gate 79 facing the first direction DR1.

Each first conductive connection structure 81 may be connected to the conductive lower connection structure LS corresponding thereto. The first conductive connection structure 81 may pass through at least one of the first insulating layer 67, the second insulating layer 69, and the third insulating layer 83 in the second area AR2 of the mold insulating structure MIS. As an embodiment, the first conductive connection structure 81 may contact the conductive lower connection structure LS corresponding thereto, and may extend in the first direction DR1 to pass through the first insulating layer 67 and the second insulating layer 69.

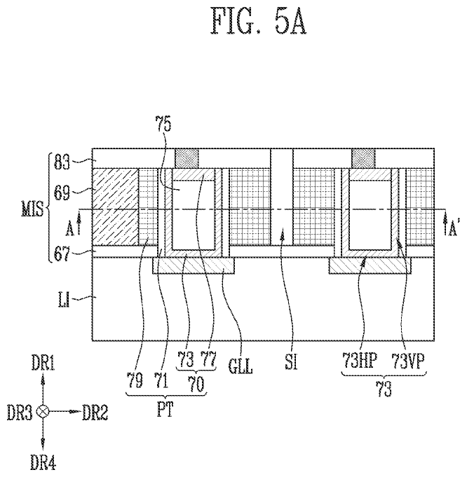

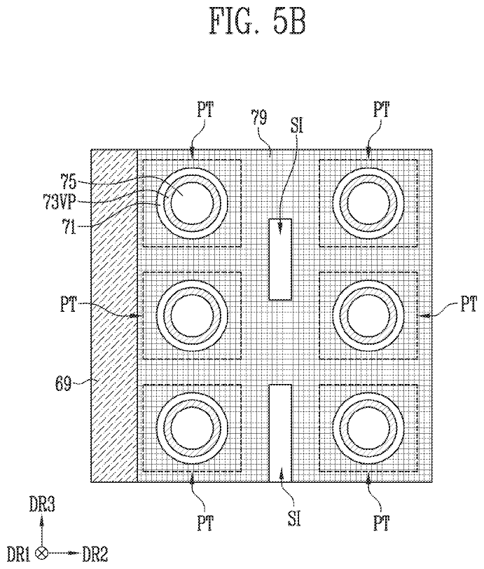

FIG. 5A is a cross-sectional view illustrating a pass transistor group according to an embodiment of the present disclosure, and FIG. 5B is a plan view illustrating the pass transistor group taken along a line A-A′ shown in FIG. 5A.

Referring to FIGS. 5A and 5B, the plurality of pass transistors PT of the pass transistor group may respectively correspond to the plurality of conductive layers CDL shown in FIG. 3 or 4.

A channel of each pass transistor PT of the pass transistor group may be defined in the active pillar 70. The active pillar 70 may be surrounded by the pass gate 79. According to this, the pass transistor PT may be formed in a surrounding gate transistor (SGT) structure. In an embodiment, as the pass transistor PT is formed in the SGT structure, the area occupied by the pass transistor PT may be reduced and an on/off characteristic of the pass transistor PT may be improved.

The pass gate 79 may be formed of a conductive material. The pass gate 79 may be spaced apart from the global line GLL and the lower insulating structure LI by the first insulating layer 67 of the mold insulating structure MIS. The pass gate 79 may be formed using a process of replacing a portion of the second insulating layer 69 of the mold insulating structure MIS with a conductive material. In order to replace a portion of the second insulating layer 69 with a conductive material, a plurality of slits SI may be formed in a process of manufacturing the semiconductor memory device. The plurality of slits SI may remain spaced apart from each other inside the pass gate 79. Each slit SI may be filled with an insulating material or a conductive material.

In order to use a process of replacing a portion of the second insulating layer 69 with a conductive material, the second insulating layer 69 may include a material having an etch selectivity with respect to the first insulating layer 67 and the third insulating layer 83. As an embodiment, each of the first insulating layer 67 and the third insulating layer 83 may include a silicon oxide layer, and the second insulating layer 69 may include a silicon nitride layer.

The active pillar 70 may pass through the first insulating layer 67 to contact the global line GLL. The active pillar 70 may include a channel layer 73 and a semiconductor capping pattern 77. The channel layer 73 and the semiconductor capping pattern 77 may include a semiconductor material such as silicon or germanium.

The channel layer 73 may pass through the first insulating layer 67 to contact the global line GLL. The channel layer 73 may include a horizontal portion 73HP and a vertical portion 73VP. The vertical portion 73VP may extend from the horizontal portion 73HP in the first direction DR1. The vertical portion 73VP may serve as a channel of the pass transistor PT. The vertical portion 73VP may be an undoped region or a doped region including at least one of a p-type impurity and an n-type impurity. The horizontal portion 73HP may be a doped region including at least one of a p-type impurity and an n-type impurity at a concentration higher than that of the vertical portion 73VP, and may be used as a source junction of the pass transistor PT.

The vertical portion 73VP of the channel layer 73 may be formed in a tubular shape. The semiconductor capping pattern 77 may be disposed in a tubular central region provided by the vertical portion 73VP. The semiconductor capping pattern 77 may be disposed at an upper end of the tubular central region, and the core insulating layer 75 may be disposed at a lower end of the tubular central region. The semiconductor capping pattern 77 may be used as a drain junction of the pass transistor PT. The semiconductor capping pattern 77 may include an impurity of the same conductivity type as the horizontal portion 73HP of the channel layer 73. As an embodiment, when the pass transistor PT is provided as an NMOS transistor, the semiconductor capping pattern 77 and the horizontal portion 73HP of the channel layer 73 may include an n-type impurity as a majority carrier.

A channel length of the pass transistor PT may be proportional to a length of the vertical portion 73VP of the channel layer 73 in the first direction DR1. In an embodiment, the length of the vertical portion 73VP may be measured in the first direction DR1. The length of the vertical portion 73VP may be proportional to a thickness of the second insulating layer 69 in the first direction DR1. In an embodiment, the thickness of the second insulating layer 69 may be measured in the first direction DR1. The channel length of the pass transistor PT may be designed to transmit a high operation voltage. The channel length of the pass transistor PT may be increased by controlling the thickness of the second insulating layer 69 in the first direction DR1. That is, in an embodiment, the channel length of the pass transistor PT may be increased even though the planar area of the semiconductor substrate 61 is not increased, and thus the planar area of the semiconductor substrate 61 allocated to the pass transistor PT may be reduced. In an embodiment, the planar area of the semiconductor substrate 61 is measured in plane formed by the first and third directions DR2 and DR3. In an embodiment, in order to secure the channel length of the pass transistor PT, the second insulating layer 69 may be formed thicker in the first direction DR1 than each of the first insulating layer 67 and the third insulating layer 83. For example, the second insulating layer 69 may have a thickness in the first direction DR1 that is greater than a total thickness equaling to the thickness of the first insulating layer 67, in the first direction DR1, added with the thickness of the third insulating layer 83, in the first direction DR1. In an embodiment, the second insulating layer 69 may be formed thicker in the first direction DR1 than the first insulating layer 67. In an embodiment, the second insulating layer 69 may be formed thicker in the first direction DR1 than the third insulating layer 83.

The pass gate insulating layer 71 may surround a sidewall of the vertical portion 73VP of the channel layer 73.

Referring to FIGS. 3 and 4, the interconnection structure of the semiconductor memory device 50A or 50B may further include a plurality of second conductive connection structures 85, a plurality of gate contact plugs GCT, a plurality of second conductive via structures V2, and a plurality of conductive lines CLI.

The plurality of second conductive connection structures 85 may be disposed inside a first intervening insulating structure IS1. The first intervening insulating structure IS1 may be disposed between the gate stack GST and the mold insulating structure MIS. The plurality of second conductive connection structures 85 may include a first type of second conductive connection structure connected to the first conductive connection structure 81 and a second type of second conductive connection structure connected to the active pillar 70. Each second conductive connection structure 85 may include a vertical via pattern and a line pattern. The plurality of second conductive connection structures 85 may pass through the third insulating layer 83 to contact the first conductive connection structure 81 or the semiconductor capping pattern 77 of the active pillar 70 shown in FIG. 5A.

The plurality of gate contact plugs GCT may be respectively connected to a plurality of conductive layers GP of the gate stack GST. The plurality of gate contact plugs GCT may extend inside the covering insulating structure CI. The plurality of gate contact plugs GCT may extend to pass through the first interlayer insulating structure 89.

The plurality of conductive second via structures V2 may be disposed inside the second interlayer insulating structure 91. The plurality of conductive second via structures V2 may be respectively connected to the plurality of gate contact plugs GCT.

A plurality of conductive lines CLI may be disposed within the bit line level insulating layer 93. Each conductive line CLI may be connected to the pass transistor PT corresponding thereto via conductive patterns of various structures.

As an embodiment, the conductive line CLI may be connected to the pass transistor PT via a first conductive bonding structure corresponding thereto among a plurality of first conductive bonding structures 87 shown in FIG. 3 and a second conductive bonding structure corresponding thereto among a plurality of second conductive bonding structures 99 shown in FIG. 3.

Referring to FIG. 3, the plurality of first conductive bonding structures 87 may be disposed inside a second intervening insulating structure IS2. The second intervening insulating structure IS2 may be disposed between the first intervening insulating structure IS1 and the gate stack GST. The plurality of first conductive bonding structures 87 may include metal such as copper. The plurality of first conductive bonding structures 87 may be respectively connected to the plurality of second conductive connection structures 85. The plurality of first conductive bonding structures 87 may be bonded to the plurality of second conductive bonding structures 99.

The plurality of second conductive bonding structures 99 may be disposed inside a third intervening insulating structure IS3. The third intervening insulating structure IS3 may be disposed between the second intervening insulating structure IS2 and the gate stack GST. The plurality of second conductive bonding structures 99 may include metal such as copper.

The interconnection structure of the semiconductor memory device 50A may further include a plurality of conductive third via structures 97. The plurality of conductive third via structures 97 may be disposed inside a fourth intervening insulating structure 95. The plurality of conductive third via structures 97 may be respectively connected to the plurality of second conductive bonding structures 99. The plurality of conductive third via structures 97 may include a first type of conductive third via structure connected to the bit line BL and a second type of conductive third via structure connected to the conductive line CLI.

The active pillar 70 of the pass transistor PT may be disposed to overlap the gate contact plug GCT. Accordingly, in an embodiment, an interconnection structure (for example, GCT, V2, CLI, and 85) for a connection between the pass transistor PT and the conductive layer CDL corresponding thereto may be simplified. Each gate contact plug GCT may contact a corresponding conductive layer among the plurality of conductive layers CDL and may extend toward the second conductive bonding structure 99. The gate contact plug GCT may be electrically connected to the active pillar 70 corresponding thereto via the conductive second via structure V2, the conductive line CLI, the second type of conductive third via structure 97, the second conductive bonding structure 99, the first conductive bonding structure 87, and the second type of second conductive connection structure 85.

The semiconductor memory device 50A shown in FIG. 3 may be provided through a process of individually performing a process of forming a first structure and a process of forming a second structure and then bonding the first structure and the second structure. The first structure may include the first peripheral circuit structure PS1 including the block decoder 33, the second peripheral circuit structure PS2 including the pass transistor PT, the first conductive connection structure 81, the second conductive connection structure 85, and the first conductive bonding structure 87. The second structure may include the cell array structure CAS, the gate contact plug GCT, the conductive bit contact plug BCT, the bit line BL, the conductive line CLI, the conductive first via structure V1, the conductive second via structure V2, the conductive third via structure 97, and the second conductive bonding structure 99. A process of bonding the first structure and the second structure may include bonding the first conductive bonding structure 87 and the second conductive bonding structure 99 to each other. The doped semiconductor structure DPS, the upper insulating layer UI, and the conductive contact CT may be formed after bonding the first structure and the second structure.

As another embodiment, as shown in FIG. 4, the gate stack GST may be interposed between the conductive line CLI and the pass transistor PT. In this case, the second type of second conductive connection structure 85 connected to the conductive line CLI and the pass transistor PT may extend to overlap a peripheral region of the semiconductor substrate 61, which is not shown in the drawing. A via contact plug (not shown) may be disposed between a portion of the conductive line CLI overlapped in the peripheral region (not shown) of the semiconductor substrate 61 and a portion of the second type of second conductive connection structure 85. The conductive line CLI may be connected to the pass transistor PT via the via contact plug.

Referring to FIG. 4, the second intervening insulating structure IS2 may be disposed between the first intervening insulating structure IS1 and the gate stack GST. The doped semiconductor structure DPS may be disposed between the second intervening insulating structure IS2 and the gate stack GST to be spaced apart from the second conductive connection structure 85.

A method of manufacturing the semiconductor memory device 50B shown in FIG. 4 may include a process of forming the first peripheral circuit structure PS1 including the block decoder 33, the second peripheral circuit structure PS2 including the pass transistor PT, and a lower structure including the first conductive connection structure 81 and the second conductive connection structure 85. A process of forming the doped semiconductor structure DPS and a process of forming the cell array structure CAS of the semiconductor memory device 50B shown in FIG. 4 may be performed over the lower structure.

Referring to FIGS. 3 and 4, in an embodiment, by disposing the pass transistor PT of the pass circuit group between the block decoder 33 and the gate stack GST, the area for the interconnection structure for a connection between the conductive layer CDL of the gate stack GST, the pass transistor PT, and the block decoder 33 may be reduced. In an embodiment, by overlapping the active pillar 70 of the pass transistor PT with the global line GLL and contacting the global line GLL, a connection between the pass transistor PT and the global line GLL may be simplified.

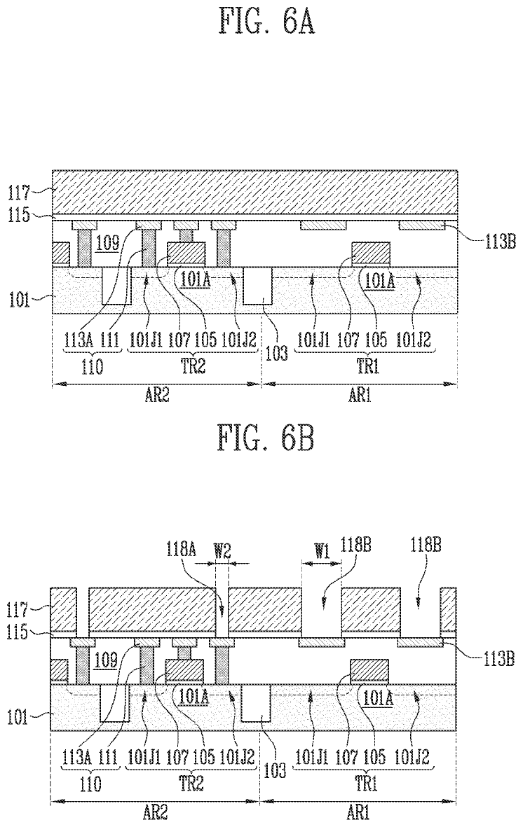

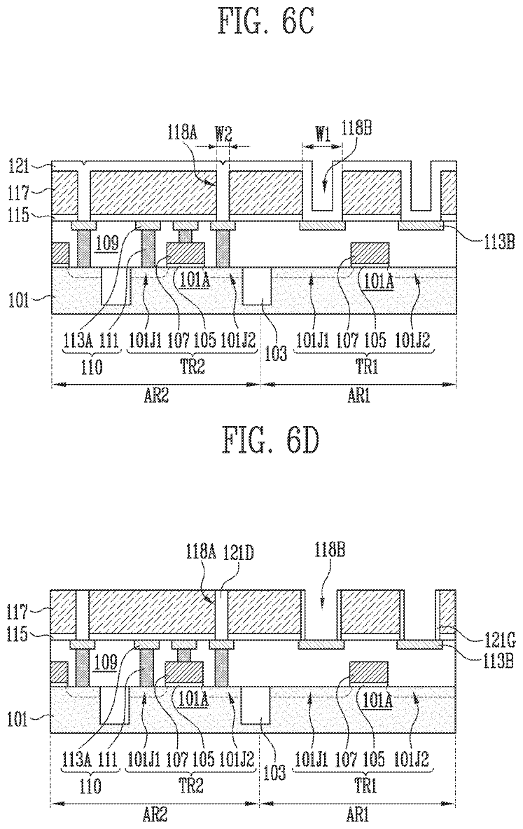

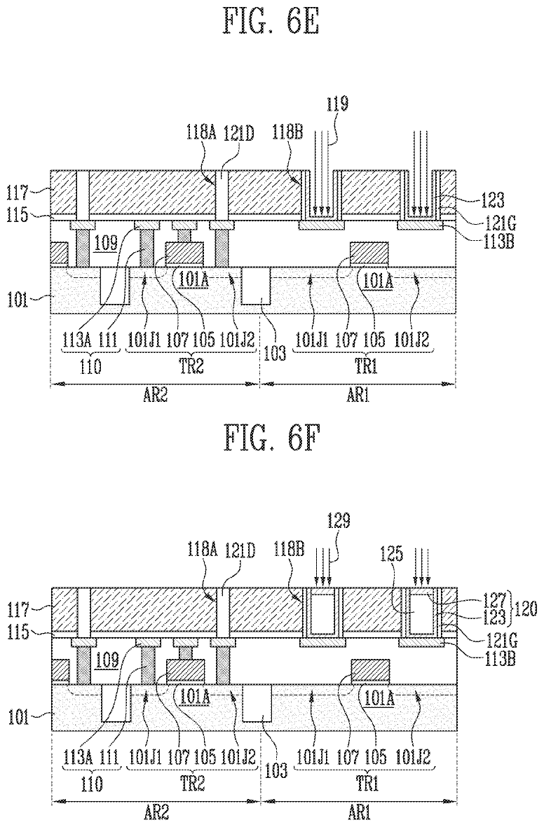

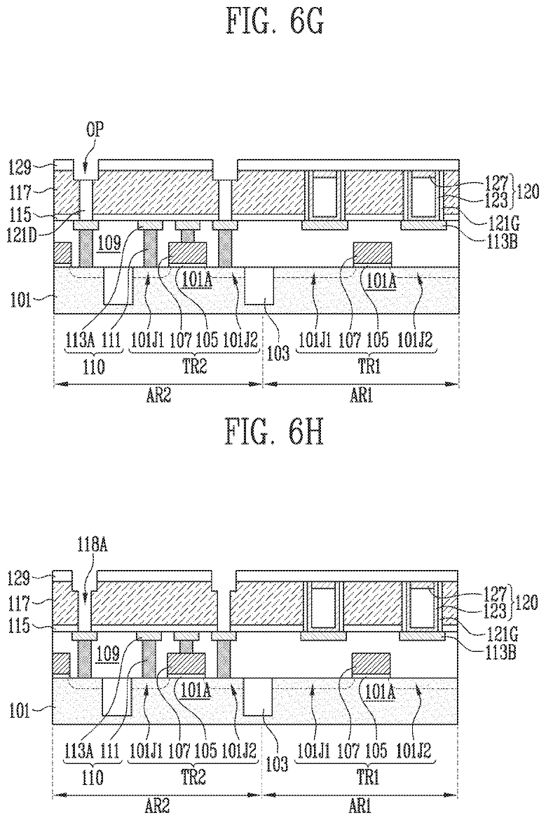

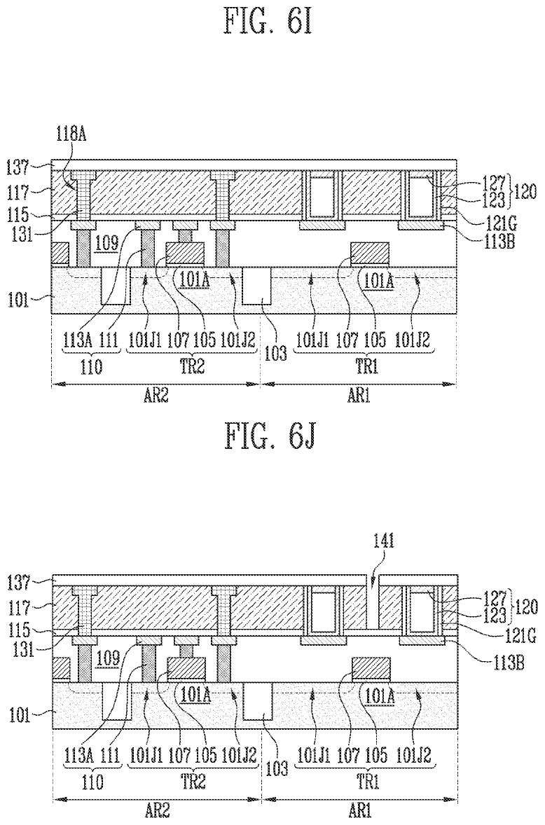

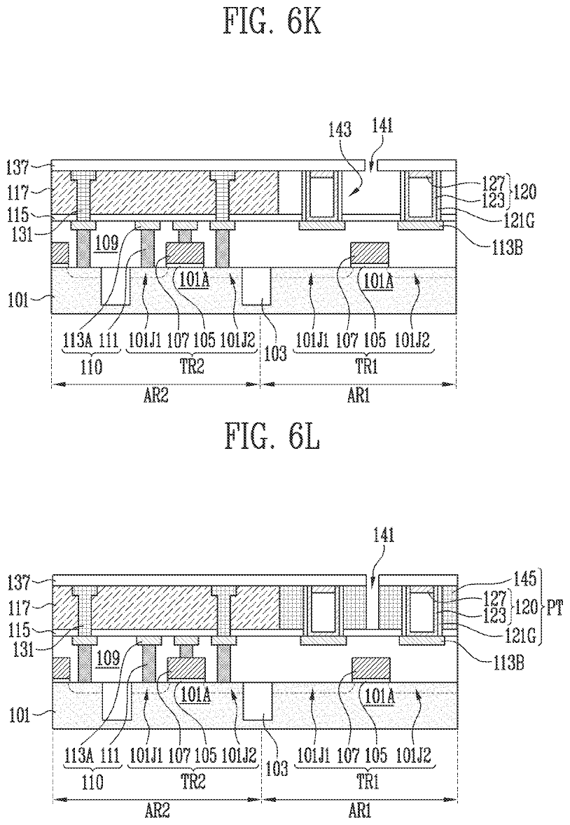

FIGS. 6A to 6L are cross-sectional views illustrating a method of manufacturing a first conductive connection structure and a pass transistor group of a semiconductor memory device according to an embodiment of the present disclosure.

Referring to FIG. 6A, a first peripheral circuit structure including a plurality of transistors TR1 and TR2 may be formed. As an embodiment, forming the first peripheral circuit structure may include forming an isolation layer 103 partitioning a plurality of active regions 101A within a semiconductor substrate 101, forming a stack structure of a gate insulating layer 105 and a gate electrode 107 on each of the plurality of active regions 101A partitioned by the isolation layer 103, and forming a first junction region 101J1 and a second junction region 101J2 by injecting a conductive impurity into the active region 101A.

As described with reference to FIGS. 3 and 4, the plurality of transistors TR1 and TR2 may include a first transistor TR1 included in a block decoder and a second transistor TR2 included in a page buffer.

Subsequently, a structure including a lower insulating structure 109 covering the plurality of transistors TR1 and TR2, a conductive lower connection structure 110 inside the lower insulating structure 109, and a global line 113B may be formed. As an embodiment, forming the structure may include forming a lower insulating layer of the lower insulating structure 109 to cover the plurality of transistors TR1 and TR2 over the semiconductor substrate 101, forming a lower via structure 111 passing through the lower insulating layer to contact one corresponding thereto among the gate electrode 107, the first junction region 101J1, and the second junction region 101J2, forming an upper insulating layer of the lower insulating structure 109 over the lower insulating layer, and forming a lower pad pattern 113A and a global line 113B in the upper insulating layer. The lower pad pattern 113A may contact the lower via structure 111. The lower via structure 111 and the lower pad pattern 113A may form the conductive lower connection structure 110. The global line 113B may be formed simultaneously with the lower pad pattern 113A using a process of forming the lower pad pattern 113A. The words “simultaneous” and “simultaneously” as used herein with respect to processes mean that the processes take place on overlapping intervals of time. For example, if a first process takes place over a first interval of time and a second process takes place simultaneously over a second interval of time, then the first and second intervals at least partially overlap each other such that there exists a time at which the first and second processes are both taking place.

Thereafter, a first insulating layer 115 may be formed over the lower insulating structure 109. The first insulating layer 115 may include a first area AR1 overlapping the block decoder including the first transistor TR1 and the global line 113B, and a second area AR2 extending laterally from the first area AR1. In an embodiment, the second area AR2 extending laterally from the first area AR1 may be in the direction directly opposite to the second direction DR2. The second area AR2 may overlap the second transistor TR2 and the conductive lower connection structure 110.

Subsequently, a second insulating layer 117 may be formed over the first insulating layer 115. The second insulating layer 117 may include a material having an etch selectivity with respect to the first insulating layer 115. As an embodiment, the first insulating layer 115 may include a silicon oxide layer, and the second insulating layer 117 may include a silicon nitride layer.

The second insulating layer 117 may extend to overlap the first area AR1 and the second area AR2 of the first insulating layer 115.

Referring to FIG. 6B, a contact hole 118A and an active hole 118B passing through the first insulating layer 115 and the second insulating layer 117 may be formed. As an embodiment, a process of forming the contact hole 118A and the active hole 118B may include forming a mask pattern (not shown) over the second insulating layer 117, etching the first insulating layer 115 and the second insulating layer 117 through a plurality of openings of the mask pattern, and removing the mask pattern. The plurality of openings of the mask pattern may respectively correspond to the contact hole 118A and the active hole 118B.

The active hole 118B may pass through the first area AR1 of the first insulating layer 115 and a portion of the second insulating layer 117 overlapping therewith. A first width W1 of the active hole 118B may be twice or more than a second width W2 of the contact hole 118A.

The contact hole 118A may pass through the second area AR2 of the first insulating layer 115 and a portion of the second insulating layer 117 overlapping therewith. The contact hole 118A may expose the conductive lower connection structure 110 corresponding thereto.

Referring to FIG. 6C, a preliminary insulating layer 121 may be formed over the second insulating layer 117. The thickness of the preliminary insulating layer 121 may be controlled to fill a central region of the contact hole 118A and to open a central region of the active hole 118B. As an embodiment, the thickness of the preliminary insulating layer 121 may be controlled to be half or more than the second width W2 and less than half the first width W1.

Referring to FIG. 6D, a portion of the preliminary insulating layer 121 shown in FIG. 6C may be etched so that the preliminary insulating layer 121 may be separated into a pass gate insulating layer 121G and a dummy insulating layer 121D. At this time, the global line 113B overlapping the active hole 118B may be exposed, and the second insulating layer 117 may be exposed.

A dummy insulating layer 121D may remain inside the contact hole 118A, and the pass gate insulating layer 121G may remain on a sidewall of the active hole 118B. The preliminary insulating layer 121 shown in FIG. 6C may be etched through an etching process such as etch-back. The pass gate insulating layer 121G remaining on the sidewall of the active hole 118B may have a reduced thickness than the preliminary insulating layer 121 shown in FIG. 6C.

Referring to FIG. 6E, in a state in which the dummy insulating layer 121D remains, a channel layer 123 may be formed inside the active hole 118B. The channel layer 123 may be formed to open the central region of the active hole 118B. The channel layer 123 may include silicon, germanium, or a mixture thereof.

The channel layer 123 may be spaced apart from the second insulating layer 117 by the pass gate insulating layer 121G. The channel layer 123 may extend along the pass gate insulating layer 121G. The channel layer 123 may extend along a surface of the global line 113B opened by the active hole 118B and may contact the global line 113B.

Subsequently, a conductive impurity 119 may be injected through the central region of the active hole 118B opened by the channel layer 123. Accordingly, a junction region may be formed in a partial region of the channel layer 123 adjacent to the global line 113B.

Referring to FIG. 6F, in a state in which the dummy insulating layer 121D remains, a core insulating layer 125 and a semiconductor capping pattern 127 may be formed in the central region of the active hole 118B opened by the channel layer 123. The semiconductor capping pattern 127 may be separated from the global line 113B by the core insulating layer 125. The semiconductor capping pattern 127 may include silicon, germanium, or a mixture thereof. The semiconductor capping pattern 127 may be doped with an impurity 129 of the same conductivity type as the junction region defined inside a partial region of the channel layer 123 adjacent to the global line 113B.

Through the processes described with reference to FIGS. 6E and 6F, an active pillar 120 may be formed to include the channel layer 123 and the semiconductor capping pattern 127 and to contact the global line 113B.

According to the series of processes described above, the active hole 118B for the active pillar 120 may be formed using a process of forming the contact hole 118A, thereby reducing the number of unit processes required to manufacture the semiconductor device.

Referring to FIG. 6G, a buffer layer 129 may be formed over the second insulating layer 117. The buffer layer 129 may include an opening OP. The opening OP may expose the dummy insulating layer 121D corresponding thereto. Subsequently, the contact hole 118A may be opened as shown in FIG. 6H by removing the dummy insulating layer 121D exposed through the opening OP.

Referring to FIG. 6H, the conductive lower connection structure 110 may be exposed by the open contact hole 118A.

Referring to FIG. 6I, a first conductive connection structure 131 may be formed inside the contact hole 118A.

As an embodiment, forming the first conductive connection structure 131 may include forming a conductive material to fill an inside of the contact hole 118A and removing a portion of the conductive material. As an embodiment, a portion of the conductive material may be removed using a planarization process such as chemical mechanical polishing (CMP) so that the second insulating layer 117 is exposed. At this time, the buffer layer 129 shown in FIG. 6H may be removed.

The process of forming the first conductive connection structure 131 and the active pillar 120 is not limited to the series of processes described above. As another embodiment, the process of forming the contact hole 118A shown in FIG. 6B may be performed before the process of forming the active hole 118B shown in FIG. 6B, and the process of forming the active hole 118B shown in FIG. 6B may be performed after filling the contact hole with the first conductive connection structure 131. The pass gate insulating layer 121G and the active pillar 120 may be formed inside the active hole after forming the first conductive connection structure 131. As still another embodiment, the process of forming the active hole 118B shown in FIG. 6B may be performed before the process of forming the contact hole 118A shown in FIG. 6B, and the process of forming the contact hole 118A shown in FIG. 6B may be performed after forming the pass gate insulating layer 121G and the active pillar 120 inside the active hole. The first conductive connection structure 131 may be formed inside the contact hole after forming the active pillar 120.

After forming the first conductive connection structure 131 and the active pillar 120 in various methods as described above, a third insulating layer 137 may be formed over the second insulating layer 117 as shown in FIG. 6I. The third insulating layer 137 may extend to cover the first conductive connection structure 131 and the active pillar 120. The third insulating layer 137 may be formed of the same material as the first insulating layer 115. As an embodiment, the third insulating layer 137 may include a silicon oxide layer.

Referring to FIG. 6J, a slit 141 passing through the second insulating layer 117 and the third insulating layer 137 may be formed. The slit 141 may overlap the first area AR1 of the first insulating layer 115.

Referring to FIG. 6K, a portion of the second insulating layer 117 exposed through the slit 141 may be selectively removed. Accordingly, a gate region 143 may be opened between the first insulating layer 115 and the third insulating layer 137. The gate region 143 may be defined around the active pillar 120 and the pass gate insulating layer 121G.

Subsequently, the gate region 143 may be filled with a pass gate 145 as shown in FIG. 6L.

Referring to FIG. 6L, the pass gate 145 may be formed by introducing a conductive material through the slit 141. The pass gate 145 may be formed to surround the active pillar 120 and the pass gate insulating layer 121G.

The second insulating layer 117 may remain between the second area AR2 of the first insulating layer 115 and the third insulating layer 137 and may face a side portion of the pass gate 145.

The slit 141 may be filled with a conductive material for the pass gate 145 or an insulating material.

Through the series of processes described above, the pass transistor PT may be formed to include the pass gate 145, the active pillar 120, and the pass gate insulating layer 121G.

Subsequently, a subsequent process for forming the second conductive connection structure, the cell array structure, and the like described with reference to FIGS. 3 and 4 may be performed.

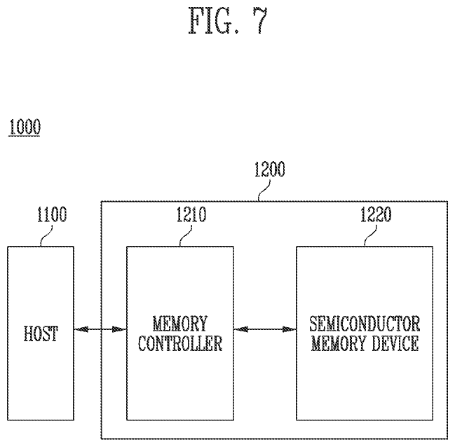

FIG. 7 is a block diagram illustrating an electronic system including a semiconductor memory device according to an embodiment of the present disclosure.

Referring to FIG. 7, the electronic system 1000 may be a computing system, a medical device, a communication device, a wearable device, a memory system, and the like. The electronic system 1000 may include a host 1100 and a storage device 1200.

The host 1100 may store data in the storage device 1200 or read data stored in the storage device 1200 based on an interface. The interface may include at least one of a double data rate (DDR) interface, a universal serial bus (USB) interface, a multimedia card (MMC) interface, an embedded MMC (eMMC) interface, a peripheral component interconnection (PCI) interface, a PCI-express (PCI-E) interface, an advanced technology attachment (ATA) interface, a serial-ATA interface, a parallel-ATA interface, a small computer system interface (SCSI), an enhanced small disk interface (ESDI), integrated drive electronics (IDE) interface, a Firewire interface, a universal flash storage (UFS) interface, and a nonvolatile memory express (NVMe) interface.

The storage device 1200 may include a memory controller 1210 and a semiconductor memory device 1220. As an embodiment, the storage device 1200 may be a storage medium such as a solid state drive (SSD) or a USB memory.

The memory controller 1210 may store data in the semiconductor memory device 1220 or read data stored in the semiconductor memory device 1220 under control of the host 1100.

The semiconductor memory device 1220 may include one memory chip or a plurality of memory chips. The semiconductor memory device 1220 may store data or output stored data under control of the memory controller 1210.

In an embodiment, the semiconductor memory device 1220 may be a nonvolatile memory device. As described with reference to FIG. 3 or 4, in an embodiment, the semiconductor memory device 1220 may include the first peripheral circuit structure, the cell array structure, the mold insulating structure disposed between the first peripheral circuit structure and the cell array structure, and the second peripheral circuit structure disposed in the mold insulating structure and including the pass transistor.

According to various embodiments of the present disclosure, the area occupied by the pass transistor may be reduced, thereby improving an integration degree of the semiconductor memory device.

What is claimed is:

1. A semiconductor memory device comprising:
a plurality of transistors;
a lower insulating structure covering the plurality of transistors;
a global line disposed within the lower insulating structure;
a mold insulating structure disposed over the lower insulating structure and including a first area overlapping the global line and a second area extending laterally from the first area;
a pass gate disposed in the first area of the mold insulating structure;
an active pillar passing through the pass gate and contacting the global line;
a pass gate insulating layer located between the active pillar and the pass gate;
a first conductive connection structure disposed in the second area of the mold insulating structure; and
a cell array structure including a plurality of memory cells arranged over the mold insulating structure.

2. The semiconductor memory device of claim 1, wherein the mold insulating structure comprises:
a first insulating layer disposed over the lower insulating structure and extending along a bottom surface of the pass gate;
a second insulating layer disposed over the first insulating layer and facing a side surface of the pass gate; and
a third insulating layer disposed over the second insulating layer and extending along an upper surface of the pass gate.

3. The semiconductor memory device of claim 2, wherein the second insulating layer includes a material having an etch selectivity with respect to the first insulating layer and the third insulating layer.

4. The semiconductor memory device of claim 1, wherein the plurality of transistors comprises:
a first transistor overlapping the first area of the mold insulating structure; and
a second transistor overlapping the second area of the mold insulating structure.

5. The semiconductor memory device of claim 4, wherein the first transistor is included in a block decoder configured to output a block select signal transmitted to the pass gate.

6. The semiconductor memory device of claim 4, further comprising:
a conductive lower connection structure disposed inside the lower insulating structure and connected to the second transistor; and
a first conductive connection structure contacting the conductive lower connection structure and extending into the second area of the mold insulating structure.

7. The semiconductor memory device of claim 1, wherein the active pillar comprises:
a channel layer including a horizontal portion contacting the global line and a vertical portion extending from the horizontal portion toward the cell array structure; and
a semiconductor capping pattern disposed in a central region of the vertical portion in the channel layer.

8. The semiconductor memory device of claim 7, wherein the horizontal portion of the channel layer and the semiconductor capping pattern include an impurity of the same conductivity type.

9. The semiconductor memory device of claim 1, further comprising:
a plurality of slits disposed spaced apart from each other inside the pass gate.

10. The semiconductor memory device of claim 1, wherein the cell array structure comprises:
a gate stack including a plurality of conductive layers spaced apart from each other and stacked in a first direction opposite to a direction toward the mold insulating structure over the mold insulating structure;
a channel layer passing through the gate stack; and
a memory layer between the channel layer and the gate stack.

11. The semiconductor memory device of claim 10, further comprising:
a first intervening insulating structure disposed between the gate stack and the mold insulating structure;
a conductive connection structure disposed inside the first intervening insulating structure and connected to the active pillar;
a second intervening insulating structure disposed between the first intervening insulating structure and the gate stack;
a first conductive bonding structure disposed inside the second intervening insulating structure and connected to the conductive connection structure;
a third intervening insulating structure disposed between the second intervening insulating structure and the gate stack;
a second conductive bonding structure disposed inside the third intervening insulating structure and bonded to the first conductive bonding structure; and
a gate contact plug extending from a conductive layer corresponding to the second conductive bonding structure among the plurality of conductive layers toward the second conductive bonding structure.

12. The semiconductor memory device of claim 10, further comprising:
a first intervening insulating structure disposed between the gate stack and the mold insulating structure;
a conductive connection structure disposed inside the first intervening insulating structure and connected to the active pillar;
a second intervening insulating structure disposed between the first intervening insulating structure and the gate stack;
a doped semiconductor structure disposed between the second intervening insulating structure and the gate stack and connected to the channel layer; and
a plurality of gate contact plugs respectively connected to the plurality of conductive layers and extending in the first direction.

13. A semiconductor memory device comprising:
a first peripheral circuit structure including a block decoder;
a gate stack spaced apart from the first peripheral circuit structure in a first direction and including a plurality of conductive layers spaced apart and stacked in the first direction;
a mold insulating structure disposed between the gate stack and the first peripheral circuit structure and including a first area overlapping the block decoder and a second area extending laterally from the first area; and
a second peripheral circuit structure disposed within the first area of the mold insulating structure and including a plurality of pass transistors configured to operate in response to a block select signal output from the block decoder.

14. The semiconductor memory device of claim 13, wherein each pass transistor of the plurality of pass transistors comprises:
a pass gate disposed in the first area of the mold insulating structure;
an active pillar passing through the pass gate; and
a pass gate insulating layer located between the active pillar and the pass gate.

15. The semiconductor memory device of claim 14, further comprising:
a lower insulating structure disposed between the first peripheral circuit structure and the mold insulating structure; and
a global line disposed within the lower insulating structure and contacting the active pillar.

16. The semiconductor memory device of claim 14, further comprising:
a plurality of slits disposed spaced apart from each other inside the pass gate.

17. The semiconductor memory device of claim 14, wherein the mold insulating structure comprises:
a first insulating layer extending along a bottom surface of the pass gate and penetrated by the active pillar;
a second insulating layer disposed over the first insulating layer and facing a side surface of the pass gate; and
a third insulating layer disposed over the second insulating layer and extending along an upper surface of the pass gate.

18. The semiconductor memory device of claim 17, wherein the second insulating layer includes a material having an etch selectivity with respect to the first insulating layer and the third insulating layer.

19. The semiconductor memory device of claim 13, further comprising:
a plurality of first conductive bonding structures connected to the plurality of pass transistors;
a channel layer passing through the gate stack;
a memory layer between the channel layer and the gate stack;
a plurality of gate contact plugs respectively contacting the plurality of conductive layers and extending toward the plurality of pass transistors; and
a plurality of second conductive bonding structures respectively connected to the plurality of gate contact plugs and respectively bonded to the plurality of first conductive bonding structures.

20. The semiconductor memory device of claim 13, further comprising:
a channel layer passing through the gate stack;
a memory layer between the channel layer and the gate stack;
a doped semiconductor structure disposed between the gate stack and the mold insulating structure and connected to the channel layer; and
a plurality of gate contact plugs respectively contacting the plurality of conductive layers and extending in the first direction.
